(19) United States
(12) Patent Application Publication
(10) Pub. No.: US 2010/0092893 A1
(43) Pub. Date: Apr. 15, 2010

(54) METHOD OF MANUFACTURING OPTICAL WAVEGUIDE DEVICE

(75) Inventors: Junichi Fujisawa, Ibaraki-shi (JP); Yusuke Shimizu, Ibaraki-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: NITTO DENKO CORPORATION, Osaka (JP)

(21) Appl. No.: 12/575,112

(22) Filed: Oct. 7, 2009

(30) Foreign Application Priority Data
Oct. 14, 2008 (JP) 2008-265418
Oct. 20, 2008 (JP) 2008-269688

(51) Int. Cl. G03F 7/20

(52) U.S. Cl. 430/321

(57) ABSTRACT

A method of manufacturing an optical waveguide device capable of suppressing the surface roughening of core side surfaces of an optical waveguide. Forming an under cladding layer on the front surface of a substrate; forming a photosensitive resin layer for core formation on a surface of the under cladding layer; wherein, in forming the cores, (A) irradiation light transmitted through the photosensitive resin layer, reaching the front surface of the substrate having an arithmetic mean roughness (Ra) in the range of 1 to 2 nm, or (B) irradiation light transmitted through the photosensitive resin layer and reflected from the bottom surface, where the front surface and back surface both have an arithmetic mean roughness (Ra) in the range of 1 to 2 nm.

### BACKGROUND OF THE INVENTION

1. Field of the Invention

The present invention relates to a method of manufacturing an optical waveguide device for widespread use in optical communications, optical information processing and other general optics.

2. Description of the Related Art

In general, an optical waveguide for an optical waveguide device is constructed such that cores serving as a passageway for light are formed in a predetermined pattern on a surface of an under cladding layer, and such that an over cladding layer is formed so as to cover the cores. Such an optical waveguide is typically formed on a surface of a substrate such as a metal substrate and the like, and is manufactured together with the substrate to provide an optical waveguide device.

A conventional method of manufacturing such an optical waveguide device is as follows. First, as shown in FIG. 4A, an under cladding layer 2 is formed on a surface of a substrate 10. Then, as shown in FIG. 4B, a photosensitive resin for the formation of cores is applied to a surface of the under cladding layer 2 to form a photosensitive resin layer 3A. Next, irradiation light L is directed through a photomask M formed with an opening pattern corresponding to the pattern of the cores toward the photosensitive resin layer 3A. The irradiation light L is caused to reach the photosensitive resin layer 3A through openings of the opening pattern, thereby exposing portions of the photosensitive resin layer 3A thereto. The irradiation light L is directed to the photosensitive resin layer 3A at right angles thereto. A photoreaction proceeds in the portions exposed to the irradiation light L so that the exposed portions are hardened. Then, development is performed using a developing solution to dissolve away unexposed portions, as shown in FIG. 4C. The remaining exposed portions become cores 3 in a predetermined pattern. The cores 3 are typically rectangular in sectional configuration. Thereafter, as shown in FIG. 4D, an over cladding layer 4 is formed on the surface of the under cladding layer 2 so as to cover the cores 3. In this manner, an optical waveguide W is formed on the surface of the substrate 10. An example of such an optical waveguide W is disclosed, for example, in Japanese Patent Application Laid-Open No. 2004-341454.

In such a conventional method, however, the side surfaces 31 of cores 30 have been roughened in some cases, as shown in FIGS. 5A and 5B. An optical waveguide having such cores 30 presents a problem in that the propagation losses of light propagating in the cores 30 are increased. FIG. 5B is a view drawn based on a photograph in perspective of a core 30 enclosed with a circle E of FIG. 5A which is magnified 700 times with an electron microscope. By magnifying the core 30 in this manner 700 times with the electron microscope, it can be seen that the side surfaces 31 of the cores 30 are roughened.

The present inventors have made studies to diagnose the cause of the formation of the roughened side surfaces 31 of the cores 30. In the course of the studies, the present inventors have found that the surface roughening of the side surfaces 31 of the cores 30 occurs, as shown in FIG. 5A, when a metal substrate 11 made of metal foil such as SUS (Steel Use Stainless) foil and the like is used as the substrate 10 (with reference to FIGS. 4A to 4D). As a result of further studies, it has been found that the metal substrate 11 made of the above-mentioned metal foil and the like includes a roughened surface having an arithmetic mean roughness (Ra) of not less than 95 nm, as shown in FIG. 5A. For this reason, in the above-mentioned core formation step, the irradiation light L for use in the exposure passes through the photosensitive resin layer 3A for the core formation and through the under cladding layer 2, and thereafter is reflected diffusely from the roughened surface of the metal substrate 11 because of the surface roughening thereof, as shown in FIG. 6. The diffusely reflected irradiation light L is transmitted through the under cladding layer 2 obliquely upwardly from below. Then, boundary surfaces (which are to become the side surfaces 31) for the patterning of the cores 30 are exposed to the diffusely reflected irradiation light L directed obliquely from below in future core regions S included in the photosensitive resin layer 3A for the core formation. The exposure to the irradiation light L directed obliquely from below results from the above-mentioned diffuse reflection, and is uneven. Thus, it has been found that an unwanted photoreaction proceeds unevenly at the surfaces which are to become the side surfaces 31 of the cores 30 because of the exposure to the irradiation light L directed obliquely from below to result in the increased width of the cores 30 and the formation of the roughened side surfaces 31 of the cores 30. In other words, the surfaces which are to become the side surfaces 31 of the cores 30 show variations in the degree of exposure to the irradiation light L or have both the unexposed portions and the exposed portions because of the diffuse reflection of the irradiation light L. In a subsequent step of development, the portions low in the degree of exposure to the irradiation light L and the unexposed portions of the surfaces which are to become the side surfaces 31 of the above-mentioned cores 30 are dissolved away, and the portions high in the degree of exposure to the irradiation light L and the exposed portions remain unremoved. Thus, the side surfaces 31 of the cores 30 are roughened.

### SUMMARY OF THE INVENTION

In view of the foregoing, it is therefore an object of the present invention to provide a method of manufacturing an optical waveguide device capable of suppressing the surface roughening of core side surfaces of an optical waveguide when the optical waveguide is formed on a surface of a substrate.

To accomplish the above-mentioned object, a method of manufacturing an optical waveguide device according to the present invention comprises the steps of: forming an under cladding layer on the front surface of a substrate; forming a photosensitive resin layer for core formation on a surface of the under cladding layer; and directing irradiation light toward the photosensitive resin layer to expose the photosensitive resin layer in a predetermined pattern to the irradiation light, thereby forming exposed portions of the photosensitive resin layer into cores, wherein, in the step of forming the cores, a combination of the irradiation light directed toward the photosensitive resin layer and the substrate is any one of the following combinations: (A) irradiation light transmitted through the photosensitive resin layer, reaching the front surface of the substrate and reflected from the front surface of the substrate, and a substrate including a front surface having an arithmetic mean roughness (Ra) in the range of Ito 2 nm, and (B) irradiation light transmitted through the photosensitive resin layer and through the front surface of the substrate, reaching the bottom surface of the substrate and reflected from the bottom surface of the substrate, and a substrate including a front surface and a back surface both having an arithmetic mean roughness (Ra) in the range of 1 to 2 nm.

The arithmetic mean roughness (Ra) according to the present invention is a surface roughness defined in JIS B 0601 (1994).

In the method of manufacturing the optical waveguide device according to the present invention, the substrate having the arithmetic mean roughness (Ra) in the range of 1 to 2 nm is used. The under cladding layer is formed on the front surface of the substrate, and then the photosensitive resin layer for the formation of the cores is formed on the under cladding layer. Thereafter, the irradiation light is directed toward the photosensitive resin layer to expose the photosensitive resin layer in the predetermined pattern to the irradiation light, thereby forming the exposed portions of the photosensitive resin layer into the cores. In the step of forming the cores, the irradiation light is directed approximately at right angles to the photosensitive resin layer for the formation of the cores, is transmitted through the photosensitive resin layer and through the under cladding layer, and reaches the front surface of the substrate. When the combination of the irradiation light and the substrate is the combination (A), that is, when the substrate is made of a material impervious to the irradiation light and the like and the irradiation light is reflected from the front surface of the substrate, the irradiation light reaching the front surface of the substrate is reflected therefrom approximately at right angles to the front surface of the substrate, is transmitted through the under cladding layer and the photosensitive resin layer, and then reaches the outside because the front surface of the substrate is so smooth as to have the arithmetic mean roughness (Ra) in the range of 1 to 2 nm. This significantly reduces the irradiation light reflected diffusely from the front surface of the substrate, transmitted through the under cladding layer obliquely upwardly from below, and reaching the photosensitive resin layer for the formation of the cores. As a result, there is little irradiation light which causes the surface roughening by exposing the future side surfaces of the cores thereto obliquely upwardly from below in the photosensitive resin layer for the formation of the cores. This effectively suppresses the surface roughening of the side surfaces of the cores. Additionally, the photosensitive resin layer is exposed again to the irradiation light reflected from the front surface of the substrate approximately at right angles. This improves the efficiency of the exposure. To eliminate the adverse effect of the above-mentioned diffuse reflection, it is contemplated that a layer for the absorption of the irradiation light is provided on the front surface of the substrate. According to the present invention, however, the diffuse reflection of the irradiation light is suppressed by making the front surface of the substrate itself smooth. This eliminates the need to provide such anew layer for the absorption of the irradiation light to offer the advantage of preventing the increase in the total thickness of the optical waveguide device.

On the other hand, when the combination of the irradiation light and the substrate is the combination (B) in the step of forming the cores, that is, when the substrate is made of a material pervious to the irradiation light and the like and the irradiation light enters the substrate and reaches the bottom surface (the surface corresponding to the back surface) of the substrate, the irradiation light reaching the front surface of the substrate is hardly refracted at the front surface because the front surface of the substrate is so smooth as to have the arithmetic mean roughness (Ra) in the range of 1 to 2 nm. The irradiation light enters the substrate approximately at right angles to the front surface of the substrate to directly reach the bottom surface of the substrate. In general, the back surface of the substrate is in contact with a mounting surface of a mounting table and the like for placing the substrate thereon, the mounting surface being impervious to the irradiation light. For this reason, the irradiation light reaching the bottom surface of the substrate does not exit from the back surface of the substrate but is reflected from the bottom surface of the substrate. The reflected irradiation light is approximately at right angles to the bottom surface of the substrate because the back surface of the substrate is so smooth as to have the arithmetic mean roughness (Ra) in the range of 1 to 2 nm. Thereafter, the reflected irradiation light is hardly refracted at the front surface of the substrate because the front surface of the substrate is smooth. The reflected irradiation light exits from the front surface of the substrate approximately at right angles to the front surface of the substrate. This significantly reduces the irradiation light refracted irregularly at the front surface of the substrate, reflected diffusely from the bottom surface of the substrate, transmitted through the under cladding layer obliquely upwardly from below, and reaching the photosensitive resin layer for the formation of the cores. As a result, there is little irradiation light which causes the surface roughening by exposing the future side surfaces of the cores thereto obliquely upwardly from below in the photosensitive resin layer for the formation of the cores. This effectively suppresses the surface roughening of the side surfaces of the cores. In this case, the irregular refraction and the diffuse reflection of the irradiation light are suppressed by the smooth front and back surfaces of the substrate. This also eliminates the need to provide a new layer for the absorption of the irradiation light to offer the advantage of preventing the increase in the total thickness of the optical waveguide device.

### BRIEF DESCRIPTION OF THE DRAWINGS

FIG. 1A is a sectional view schematically showing an optical waveguide device provided by a method of manufacturing an optical waveguide device according to a first embodiment of the present invention.

FIG. 1B is a perspective view drawn based on a photograph of a core enclosed with a circle E of FIG. 1A which is magnified with an electron microscope.

FIGS. 2A to 2D are illustrations schematically showing the manufacturing method according to the first embodiment of the present invention.

FIG. 3 is an illustration schematically showing the step of directing irradiation light to a photosensitive resin layer for core formation in the manufacturing method according to a second embodiment of the present invention.

FIGS. 4A to 4D are illustrations schematically showing a conventional method of manufacturing an optical waveguide device.

FIG. 5A is a sectional view schematically showing the formation of cores in the conventional manufacturing method.

FIG. 5B is a perspective view drawn based on a photograph of a core enclosed with a circle E of FIG. 5A which is magnified with an electron microscope.

FIG. 6 is an illustration schematically showing a situation in the step of forming the cores in the conventional manufacturing method.

### DESCRIPTION OF THE EMBODIMENTS

Embodiments according to the present invention will now be described in detail with reference to the drawings.

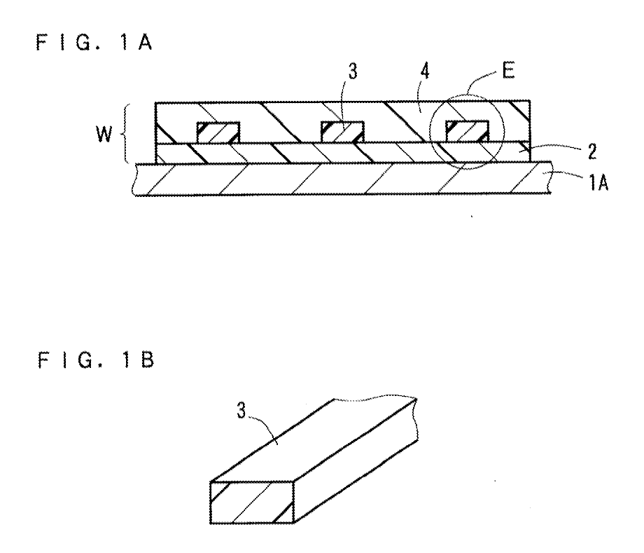

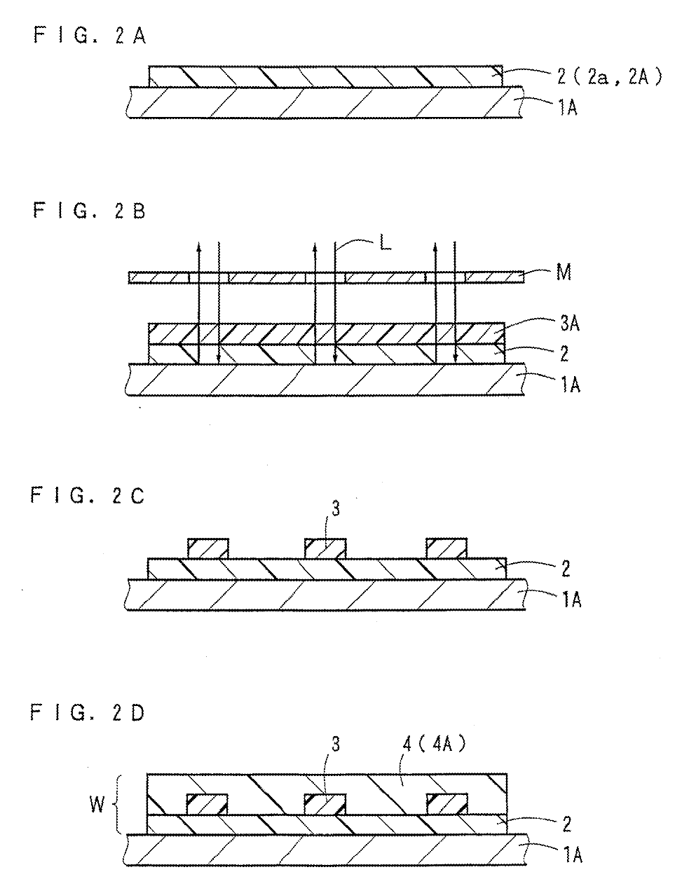

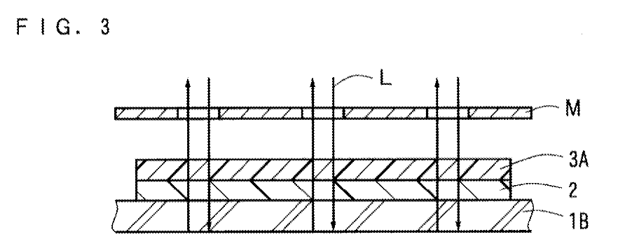

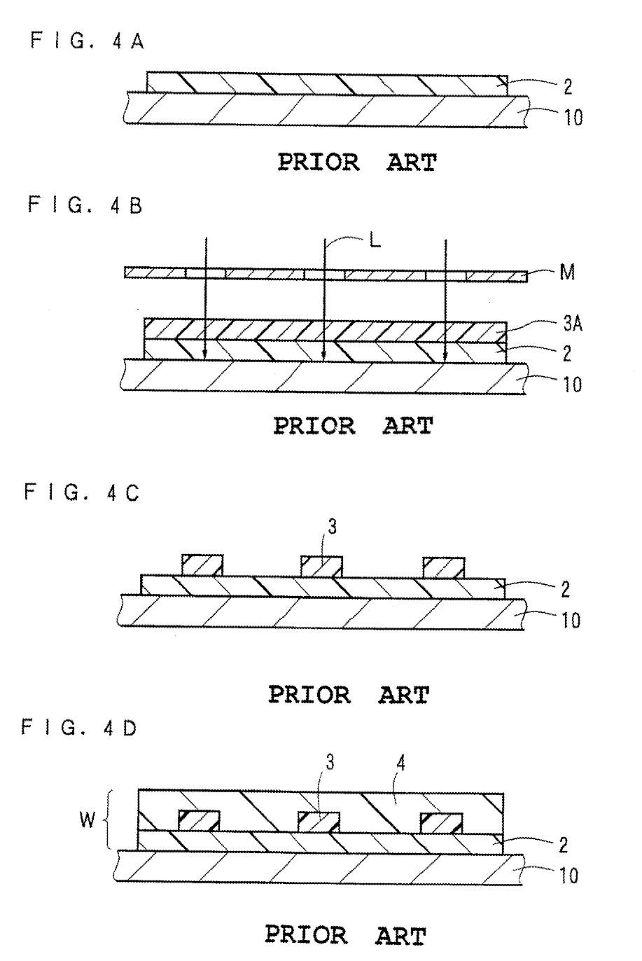

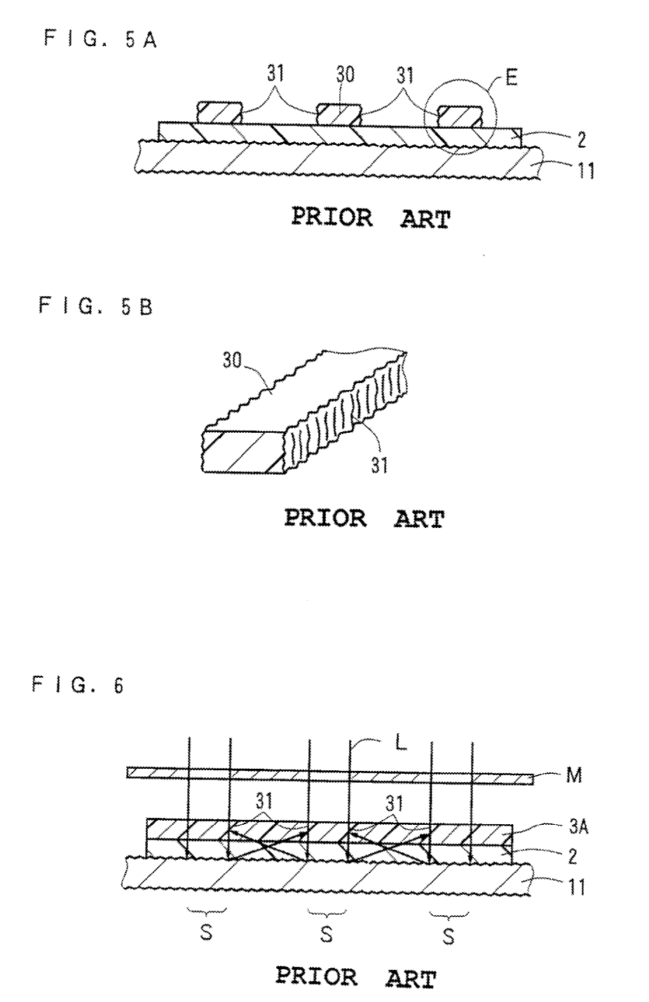

FIG. 1A shows an optical waveguide device provided by a method of manufacturing an optical waveguide device according to a first embodiment of the present invention. This optical waveguide device includes a substrate 1A made of a material impervious to irradiation light and including a front surface having an arithmetic mean roughness (Ra) in the range of 1 to 2 nm, and an optical waveguide W formed on the front surface of the substrate 1A. The optical waveguide W includes an under cladding layer 2 formed on the front surface of the substrate 1A, and is manufactured in a manner to be described below. First, a photosensitive resin layer 3A (with reference to FIG. 2B) is formed on a surface of the under cladding layer 2. Thereafter, irradiation light L is directed toward the photosensitive resin layer 3A to expose the photosensitive resin layer 3A in a predetermined pattern to the irradiation light L, thereby forming cores 3. Further, an over cladding layer 4 is formed over the cores 3 in a stacked manner. The optical waveguide W is thus manufactured. The material of the substrate 1A which is impervious to irradiation light performs the function of preventing the irradiation light L directed to the photosensitive resin layer 3A from passing through the substrate 1A. FIG. 1B is a perspective view drawn based on a photograph of a core 3 enclosed with a circle E of FIG. 1A which is magnified 700 times with an electron microscope.

The method of manufacturing the optical waveguide device according to the first embodiment will be described in detail.

First, the substrate 1A (with reference to FIG. 2A) is prepared. The substrate 1A is made of the material impervious to the irradiation light L such as ultraviolet light and the like for use in exposure of the photosensitive resin layer 3A for the formation of the cores 3 thereto in a subsequent step of forming the cores 3 (with reference to FIGS. 2B and 2C), and the front surface of the substrate 1A is so smooth as to have the arithmetic mean roughness (Ra) in the range of 1 to 2 nm, as mentioned earlier. An example of such a substrate 1A includes a silicon wafer (a substrate made of silicon) or the like. The substrate 1A used typically is commercially available. For example, the above-mentioned silicon wafer, which is typically used for the manufacture of semiconductor devices, is formed to have a smooth front surface for the purposes of the construction of defect-free stacked interconnect lines and the improvements in yield. Substrates other than the above-mentioned silicon wafer are also necessarily smoothed in the manufacture process thereof. Additionally, a substrate made of a material impervious to the irradiation light L and having a front surface that is roughened when on the market, e.g. a metal substrate such as a stainless steel substrate, an aluminum substrate, a copper substrate and the like, may be used as the substrate 1A if such a substrate is surface-treated so that the front surface thereof is smoothed by polishing to have the above-mentioned arithmetic mean roughness (Ra) in the range of 1 to 2 nm. The substrate 1A used herein has a thickness, for example, in the range of 20 μm to 1 mm.

Next, as shown in FIG. 2A, a varnish prepared by dissolving a photosensitive resin for the formation of the under cladding layer 2 in a solvent is applied to a predetermined region of the front surface of the substrate 1A to form a coating layer 2a. Examples of the above-mentioned photosensitive resin include a photosensitive epoxy resin and the like. The application of the above-mentioned varnish is achieved, for example, by a spin coating method, a dipping method, a casting method, an injection method, an ink jet method and the like. Then, the coating layer 2a is dried by a heating treatment at 50 to 120° C. for 10 to 30 minutes, as required. This provides a photosensitive resin layer 2A for the formation of the under cladding layer 2.

Next, the photosensitive resin layer 2A is exposed to irradiation light. Examples of the irradiation light for the exposure used herein include visible light, ultraviolet light, infrared light, X-rays, alpha rays, beta rays, gamma rays and the like. Preferably, ultraviolet light (with a wavelength of 250 to 400 nm) is used. This is because the use of ultraviolet light achieves irradiation with large energy to provide a high rate of hardening, and an irradiation apparatus therefor is small in size and inexpensive to achieve the reduction in production costs. A light source of the ultraviolet light may be, for example, a low-pressure mercury-vapor lamp, a high-pressure mercury-vapor lamp, an ultra-high-pressure mercury-vapor lamp, and the like. The dose of the ultraviolet light is typically 10 to 10000 mJ/cm², preferably 50 to 3000 mJ/cm².

After the above-mentioned exposure, a heating treatment is performed to complete a photoreaction. This heating treatment is performed at 80 to 250° C., preferably at 100 to 200° C., for 10 seconds to two hours, preferably for five minutes to one hour. This causes the photosensitive resin layer 2A to be formed into the under cladding layer 2, as shown in FIG. 2A. The thickness of the under cladding layer 2 is typically in the range of 1 to 50 μm, preferably in the range of 5 to 30 μm.

Next, as shown in FIG. 2B, the photosensitive resin layer 3A for the formation of the cores 3 (with reference to FIG. 2C) is formed on the surface of the under cladding layer 2. The formation of the photosensitive resin layer 3A is carried out in a manner similar to the process for forming the photosensitive resin layer 2A for the formation of the under cladding layer 2, which is described with reference to FIG. 2A. A material for the formation of the cores 3 used herein has a refractive index higher than that of the material for the formation of the under cladding layer 2 and the over cladding layer 4 (with reference to FIG. 2D) to be described later. The adjustment of the refractive indices may be made, for example, by adjusting the selection of the types of the materials for the formation of the under cladding layer 2, the cores 3 and the over cladding layer 4 described above and the composition ratio thereof.

Thereafter, a photomask M formed with an opening pattern corresponding to the cores 3 is placed over the photosensitive resin layer 3A for the formation of the cores 3. Portions of the photosensitive resin layer 3A corresponding to the above-mentioned opening pattern are exposed to the irradiation light L through this photomask M. This exposure is performed in a manner similar to that in the step of forming the under cladding layer 2 mentioned earlier. During the exposure, the irradiation light L impinges upon the photosensitive resin layer 3A at right angles thereto to cause the photoreaction to proceed in the portions exposed to the irradiation light L, thereby hardening the exposed portions. The irradiation light L is transmitted through the photosensitive resin layer 3A and through the under cladding layer 2 to reach the front surface of the substrate 1A. Since the substrate 1A is made of the material impervious to the irradiation light L and includes the front surface so smooth as to have the arithmetic mean roughness (Ra) in the range of 1 to 2 nm, the irradiation light L that has reached the front surface of the substrate 1A is reflected therefrom approximately at right angles to the front surface of the substrate 1A. This significantly reduces the irradiation light L reflected diffusely from the front surface of the substrate 1A and transmitted through the under cladding layer 2 obliquely upwardly from below. As a result, there is little irradiation light L to which future side surfaces (the surfaces that are to become the side surfaces) of the cores 3 are exposed due to the diffuse reflection thereof in the photosensitive resin layer 3A for the formation of the cores 3. This suppresses the surface roughening of the side surfaces of the cores 3. Additionally, the photosensitive resin layer 3A is exposed again to the reflected irradiation light L. This improves the efficiency of the exposure.

After the exposure, a heating treatment is performed in a manner similar to that in the step of forming the under cladding layer 2 mentioned earlier. Then, development is performed using a developing solution. This dissolves away unexposed portions of the photosensitive resin layer 3A to cause the portions of the photosensitive resin layer 3A remaining on the under cladding layer 2 to be formed into the pattern of the cores 3, as shown in FIG. 2C. The development employs, for example, an immersion method, a spray method, a puddle method and the like. Examples of the developing solution used herein include an organic solvent, an organic solvent containing an alkaline aqueous solution, and the like. The developing solution and conditions for the development are selected as appropriate depending on the composition of the photosensitive resin.

After the development, the developing solution remaining on the surface and the like of the photosensitive resin layer 3A formed in the pattern of the cores 3 is removed by a heating treatment. This heating treatment is performed typically at 80 to 120° C. for 10 to 30 minutes. This causes the photosensitive resin layer 3A formed in the pattern of the cores 3 to be formed into the cores 3. The surface roughening of the side surfaces of the cores 3 is suppressed, as mentioned earlier. The thickness of the cores 3 is typically in the range of 5 to 150 μm, preferably in the range of 5 to 100 μm. The width of the cores 3 is typically in the range of 5 to 150 μm, preferably in the range of 5 to 100 μm.

Next, as shown in FIG. 2D, a photosensitive resin layer 4A for the formation of the over cladding layer 4 is formed on the surface of the under cladding layer 2 so as to cover the cores 3. The formation of this photosensitive resin layer 4A is carried out in a manner similar to the process for forming the photosensitive resin layer 2A for the formation of the under cladding layer 2, which is described with reference to FIG. 2A. Thereafter, exposure to light, a heating treatment and the like are performed in a manner similar to those in the step of forming the under cladding layer 2 to cause the photosensitive resin layer 4A to be formed into the over cladding layer 4. The thickness of the over cladding layer 4 (as measured from the surface of the cores 3) is typically in the range of 5 to 100 μm, preferably in the range of 10 to 80 μm.

In this manner, an optical waveguide device is provided in which the optical waveguide W including the under cladding layer 2, the cores 3 and the over cladding layer 4 described above is formed on the front surface of the substrate 1A. The optical waveguide W in this optical waveguide device has low light propagation losses to achieve good propagation of light because the surface roughening of the side surfaces of the cores 3 is suppressed.

FIG. 3 shows the step of directing the irradiation light L to the photosensitive resin layer 3A for the formation of the cores 3 in the manufacturing method according to a second embodiment of the present invention. In the second embodiment, a substrate 1B made of a material pervious to the irradiation light L and including front and back surfaces both so smooth as to have an arithmetic mean roughness (Ra) in the range of 1 to 2 nm is used. An example of such a substrate 1B includes a glass substrate or the like. The substrate 1B used typically is also commercially available, and is necessarily smoothed in the manufacture process thereof. Additionally, a substrate made of a material pervious to the irradiation light L and having both front and back surfaces that are roughened when on the market may be used as the substrate 1B if such a substrate is surface-treated so that the front and back surfaces thereof are smoothed by polishing to have the above-mentioned arithmetic mean roughness (Ra) in the range of 1 to 2 nm. Other parts in the second embodiment are similar to those in the first embodiment. Like reference numerals and characters are used to designate parts similar to those in the first embodiment.

In the second embodiment, the irradiation light L is directed at right angles to the photosensitive resin layer 3A, is transmitted through the photosensitive resin layer 3A and through the under cladding layer 2, and reaches the front surface of the substrate 1B. Such irradiation light L is hardly refracted at the front surface of the substrate 1B because the front surface of the substrate 1B is so smooth as to have the arithmetic mean roughness (Ra) in the range of 1 to 2 nm. The irradiation light L enters the substrate 1B approximately at right angles to the front surface of the substrate 1B to directly reach the bottom surface (the surface corresponding to the back surface) of the substrate 1B. The irradiation light L reaching the bottom surface of the substrate 1B is reflected therefrom approximately at right angles to the bottom surface of the substrate 1B because the back surface of the substrate 1B is also so smooth as to have the arithmetic mean roughness (Ra) in the range of 1 to 2 nm. Thereafter, the reflected irradiation light L is hardly refracted at the front surface of the substrate 1B because the front surface of the substrate 1B is smooth. The reflected irradiation light L exits from the front surface of the substrate 1B approximately at right angles to the front surface of the substrate 1B. This significantly reduces the irradiation light L refracted irregularly at the front surface of the substrate 1B, reflected diffusely from the bottom surface of the substrate 1B and transmitted through the under cladding layer 2 obliquely upwardly from below. As a result, there is little irradiation light L to which the future side surfaces of the cores 3 are exposed due to the diffuse reflection thereof in the photosensitive resin layer 3A for the formation of the cores 3, as in the first embodiment described above. This suppresses the surface roughening of the side surfaces of the cores 3. Additionally, the photosensitive resin layer 3A is exposed again to the reflected irradiation light L, as in the first embodiment described above. This improves the efficiency of the exposure.

In the first and second embodiments described above, no components are formed on the back surface of each of the substrates 1A and 1B (the surface opposite from the surface on which the optical waveguide W is formed). However, each of the substrates 1A and 1B may be a substrate having a back surface on which an electric circuit is formed, with an insulation layer therebetween, or a substrate such that the electric circuit is formed with mounting pads on which optical elements such as a light-emitting element, a light-receiving element and the like are mounted.

In the first and second embodiments described above, the over cladding layer 4 is formed. However, the over cladding layer 4 may be dispensed with in some instances.

Next, inventive examples of the present invention will be described in conjunction with a comparative example. It should be noted that the present invention is not limited to the inventive examples.

### EXAMPLES

### Inventive Example 1

### Substrate

A substrate which was a silicon wafer [available from Silicon Technology Co., Ltd., and having a thickness of 525 μm and an arithmetic mean roughness (Ra) of 1 nm] was prepared. A color 3D laser microscope (VK-9700 available from Keyence Corporation) was used for the measurement of the arithmetic mean roughness (Ra), and the range of measurement was 200 μm by 200 μm (also in Inventive Example 2 and Comparative Example to be described later).

### Material for Formation of Under Cladding Layer and Over Cladding Layer

A material for formation of an under cladding layer and an over cladding layer was prepared by mixing 35 parts by weight of bisphenoxyethanol fluorene glycidyl ether (component A) represented by the following general formula (1), 40 parts by weight of 3′,4′-epoxycyclohexyl methyl 3,4-epoxycyclohexanecarboxylate (an alicyclic epoxy resin CELLOXIDE 2021P manufactured by Daicel Chemical Industries, Ltd.) (Component B), 25 parts by weight of (3′,4′-epoxycyclohexane)methyl 3′,4′-epoxycyclohexyl carboxylate (CELLOXIDE 2081 manufactured by Daicel Chemical Industries, Ltd.) (Component C), and 2 parts by weight of a 50% propione carbonate solution of 4,4′-bis[di(β-hydroxyethoxy)phenylsulfinio] phenylsulfide bishexafluoroantimonate (Component D).

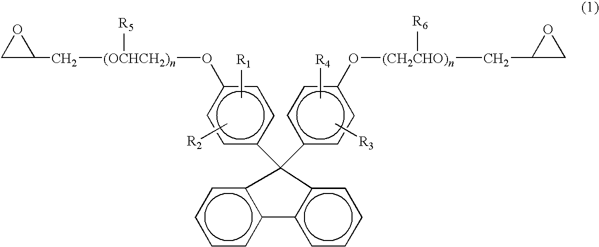

wherein R₁ to R₆ are hydrogen atoms, and n=1.

### Material for Formation of Cores

A material for formation of cores was prepared by dissolving 70 parts by weight of the aforementioned component A, 30 parts by weight of 1,3,3-tris{4-[2-(3-oxetanyl)]butoxyphenyl}butane and one part by weight of the aforementioned component D in ethyl lactate.

### Manufacture of Optical Waveguide Device

The material for the formation of the under cladding layer was applied to the front surface of the above-mentioned substrate by using a spin coater to form a coating layer having a thickness of 20 μm. Thereafter, the entire surface of the coating layer was irradiated with ultraviolet light from an ultra-high-pressure mercury-vapor lamp so as to be exposed to the ultraviolet light at an integrated dose of 1000 mJ/cm² (based on an i-line standard). Subsequently, the exposed coating layer was allowed to stand for ten minutes on a hotplate at 120° C. so that the reaction was completed. In this manner, the under cladding layer was formed.

Then, the material for the formation of the cores was applied to a surface of the under cladding layer by using a spin coater, and thereafter was allowed to stand for five minutes on a hot plate at 70° C. so that the solvent was volatilized. Thus, a photosensitive resin layer for the formation of the cores was formed. Next, ultraviolet light was emitted from an ultra-high-pressure mercury-vapor lamp through a glass mask formed with a predetermined opening pattern (having an opening width of 50 μm, and a spacing of 200 μm between adjacent openings) so that the photosensitive resin layer was exposed to the ultraviolet light at an integrated dose of 2000 mJ/cm² (based on an i-line standard). Thereafter, the exposed photosensitive resin layer was allowed to stand for ten minutes on a hot plate at 120° C. so that the reaction was completed. Next, development was performed with a spray developing machine using a developing solution including 90% by weight of γ-butyrolactone. Thus, the cores (having a height of 50 μm) was formed.

Then, the material for the formation of the over cladding layer was applied to the surface of the under cladding layer by using a spin coater so as to cover the cores. Thereafter, the over cladding layer was formed in a manner similar to the process for forming the under cladding layer. In this manner, an optical waveguide device (having a total thickness of 100 μm) was manufactured.

### Inventive Example 2

An optical waveguide device was manufactured by forming the under cladding layer, the cores and the over cladding layer directly on the front surface of a glass substrate [available from Central Glass Co., Ltd., and having a thickness of 1100 μm and an arithmetic mean roughness (Ra) of 2 nm] in a manner similar to that in Inventive Example 1 described above.

### Comparative Example

An optical waveguide device was manufactured by forming the under cladding layer, the cores and the over cladding layer directly on the front surface of SUS 304 foil [available from Toyo Seihaku Co., Ltd., and having a thickness of 20 μm and an arithmetic mean roughness (Ra) of 95 nm] in a manner similar to that in Inventive Example 1 described above.

### Evaluation of Core Side Surfaces

The side surfaces of the cores of the optical waveguide devices in Inventive Examples 1 and 2, and Comparative Example described above were observed with a scanning electron microscope. As a result, the side surfaces of the cores in Comparative Example were roughened surfaces, but the side surfaces of the cores in Inventive Examples 1 and 2 were much more flattened than those in Comparative Example.

### Measurements of Core Width

Measurements of the widths of the cores of the optical waveguide devices in Inventive Examples 1 and 2, and Comparative Example described above were made with a scanning electron microscope. As a result, the cores had a width of 54 μm in Inventive Example 1, a width of 53 μm in Inventive Example 2, and a width of 57.7 μm in Comparative Example. It should be noted that each of the above-mentioned values of the widths of the cores is the average of the values of measurements in ten arbitrary locations.

### Measurements of Light Propagation Loss

The optical waveguide devices in Inventive Examples 1 and 2, and Comparative Example described above were cut using a dicing machine (DAD522 available from Disco Corporation) so that the end surfaces of the cores were uncovered. Also, the optical waveguide devices were cut to a length of 10 cm, and light propagation losses were measured. As a result, the optical waveguide device had a light propagation loss of 1.73 dB/10 cm in Inventive Example 1, a light propagation loss of 1.66 dB/10 cm in Inventive Example 2, and a light propagation loss of 5.22 dB/10 cm in Comparative Example.

The above-mentioned results show that little diffuse reflection from the surfaces of the substrate occurs in Inventive Examples 1 and 2 because the surface roughening of the core side surfaces is suppressed in Inventive Examples 1 and 2, as compared with Comparative Example. This is because the surfaces of the substrate are so smooth as to have a low degree of arithmetic mean roughness (Ra) in Inventive Examples 1 and 2.

Although a specific form of embodiment of the instant invention has been described above and illustrated in the accompanying drawings in order to be more clearly understood, the above description is made by way of example and not as a limitation to the scope of the instant invention. It is contemplated that various modifications apparent to one of ordinary skill in the art could be made without departing from the scope of the invention which is to be determined by the following claims.

What is claimed is:

1. A method of manufacturing an optical waveguide device, comprising the steps of:
preparing a substrate including a front surface having an arithmetic mean roughness (Ra) in the range of 1 to 2 nm;
forming an under cladding layer on the front surface of the substrate;
forming a photosensitive resin layer for core formation on a surface of the under cladding layer; and
directing irradiation light toward the photosensitive resin layer to expose the photosensitive resin layer in a predetermined pattern to the irradiation light, thereby forming exposed portions of the photosensitive resin layer into cores,
wherein, in the step of forming the cores, the irradiation light is transmitted through the photosensitive resin layer, reaches the front surface of the substrate, and is then reflected from the front surface of the substrate.

2. The method according to claim 1, wherein the substrate is a silicon wafer.

3. A method of manufacturing an optical waveguide device, comprising the steps of:
preparing a substrate including a front surface and aback surface both having an arithmetic mean roughness (Ra) in the range of 1 to 2 nm;
forming an under cladding layer on the front surface of the substrate;
forming a photosensitive resin layer for core formation on a surface of the under cladding layer; and
directing irradiation light toward the photosensitive resin layer to expose the photosensitive resin layer in a predetermined pattern to the irradiation light, thereby forming exposed portions of the photosensitive resin layer into cores,
wherein, in the step of forming the cores, the irradiation light is transmitted through the photosensitive resin layer and through the front surface of the substrate, reaches the bottom surface of the substrate, and is then reflected from the bottom surface of the substrate.

4. The method according to claim 3, wherein the substrate is a glass substrate.
